(19) United States
(12) Patent Application Publication
(10) Pub. No.: US 2026/0250463 A1
(43) Pub. Date: Aug. 27, 2026

(54) POLYAMIDEIMIDE AND POLYAMIDEIMIDE FILM

(71) Applicant: Resonac Corporation, Tokyo (JP)

(72) Inventors: Saori MIURA, Tokyo (JP); Atsushi TAKAHASHI, Tokyo (JP)

(21) Appl. No.: 18/861,706

(22) PCT Filed: Apr. 20, 2023
(86) PCT No.: PCT/JP2023/015773

§ 371 Date: Oct. 30, 2024

(30) Foreign Application Priority Data
Jun. 2, 2022 (JP) 2022-090058

(51) Int. Cl. C08G 73/14; C08J 5/18

(52) U.S. Cl. CPC C08G 73/14; C08J 5/18; C08J 2379/08

(57) ABSTRACT

An embodiment relates to a polyamideimide, including: a structure derived from a compound including at least one selected from the group consisting of a diamine and a diisocyanate, and a structure derived from a carboxylic acid compound including at least a tricarboxylic anhydride, wherein at least one selected from the compound and the carboxylic acid compound includes a compound having a group that includes at least one non-aromatic hydrocarbon group, where a total number of carbon atoms in the at least one non-aromatic hydrocarbon group is eight or more, and at least one selected from the compound and the carboxylic acid compound includes a compound having an aromatic hydrocarbon group.

### FIELD

The present disclosure relates to a polyamideimide, a polyamideimide containing liquid, a polyamideimide film, and a printed board.

### BACKGROUND

Polyamideimides are widely used in various applications because of their excellent electrical insulating properties, heat resistance, chemical resistance, and solvent resistance. For example, polyamideimides are used as a material for varnishes for enamel wires, protective films for electronic components, optical or display films, and the like (Patent Literature 1).

### CITATION LIST

### Patent Literature

Patent Literature 1: JP 2012-87236 A

### SUMMARY

### Technical Problem

In recent years, there has been a demand for high integration and high frequency electronic components, and it is desired to further improve permittivity properties of insulating materials in a wide frequency range including high frequencies. The present disclosure thus provides a polyamideimide having a low permittivity and a low dielectric loss tangent, and a polyamideimide containing liquid containing the polyamideimide. The present disclosure also provides a polyamideimide film and a printed board that exhibit excellent insulating properties.

### Solution to Problem

The present invention includes the following embodiments. The present invention is not limited to the following embodiments.

One embodiment relates to a polyamideimide, including: a structure derived from a compound including at least one selected from the group consisting of a diamine and a diisocyanate, and a structure derived from a carboxylic acid compound including at least a tricarboxylic anhydride, wherein at least one selected from the compound and the carboxylic acid compound includes a compound having a group that includes at least one non-aromatic hydrocarbon group, where a total number of carbon atoms in the at least one non-aromatic hydrocarbon group is eight or more, and at least one selected from the compound and the carboxylic acid compound includes a compound having an aromatic hydrocarbon group.

Another embodiment relates to a polyamideimide containing liquid, including the above polyamideimide, and a solvent.

Another embodiment relates to a polyamideimide film obtained by using the above polyamideimide, or the above polyamideimide containing liquid.

Another embodiment relates to a printed board obtained by using the above polyamideimide, or the polyamideimide containing liquid.

### Advantageous Effects of Invention

According to the present disclosure, it is possible to provide a polyamideimide having a low permittivity and a low dielectric loss tangent, and a polyamideimide containing liquid containing the polyamideimide. It is also possible to provide a polyamideimide film and a substrate exhibiting excellent insulation properties.

### DESCRIPTION OF EMBODIMENTS

Embodiments of the present invention will be described. The present invention is not limited to the following embodiments. The following embodiments can be implemented alone or in combination. Combinations of multiple embodiments are also included in the present invention.

In numerical ranges described step by step in the present disclosure, an upper or lower limit of a numerical range may be replaced with an upper or lower limit of another numerical range. An upper or lower limit of a numerical range described in the present disclosure may be replaced with a value indicated in examples. A certain numerical value may be selected from the upper limit numerical values described step by step in the present disclosure, and a certain numerical value may be selected from the lower limit numerical values described step by step in the present disclosure, to form another step by step numerical range. An upper limit numerical value and a lower limit numerical value described in the present disclosure may be replaced with values indicated in examples.

In the present disclosure, each component may include multiple types of substances corresponding therewith. When there are multiple types of substances corresponding with each component in a composition, the content or amount contained of each component means, unless otherwise specified, the total content or the total amount contained of the multiple types of substances present in the composition.

In the present disclosure, each structure in a polymer may include multiple types of structures corresponding therewith. When there are multiple types of structures corresponding with each structure in a polymer, the content or amount contained of each structure means, unless otherwise specified, the total content or the total amount contained of the multiple types of structures present in the polymer.

In the present disclosure, “layer” includes a continuous layer and a discontinuous layer. The thickness of the “layer” may be uniform or non-uniform. Outer edges in a plane direction and outer edges in a thickness direction of the “layer” may each be clear or unclear. The same applies to “membrane”.

### <Polyamideimide>

In an embodiment of the present invention, a polyamideimide includes a structure derived from a compound including at least one selected from the group consisting of a diamine and a diisocyanate, and a structure derived from a carboxylic acid compound including at least a tricarboxylic anhydride. At least one selected from the compound and the carboxylic acid compound includes a compound having a group that includes at least one non-aromatic hydrocarbon group, where the total number of carbon atoms in the at least one non-aromatic hydrocarbon group is eight or more. Also, at least one selected from the compound and the carboxylic acid compound includes a compound having an aromatic hydrocarbon group. In the present disclosure, “a compound including at least one selected from the group consisting of a diamine and a diisocyanate” may be referred to as “a diamine or diisocyanate compound”. The carboxylic acid compound may further include a dicarboxylic acid. In the present disclosure, “a group including at least one non-aromatic hydrocarbon group, where the total number of carbon atoms in the at least one non-aromatic hydrocarbon group is eight or more” may be referred to as “hydrocarbon group (X)”.

In the polyamideimide, for example, at least a diamine or diisocyanate compound includes a compound having a hydrocarbon group (X), and at least a carboxylic acid compound includes a compound having an aromatic hydrocarbon group. Alternatively, in the polyamideimide, for example, at least a diamine or diisocyanate compound includes a compound having an aromatic hydrocarbon group, and at least a carboxylic acid compound includes a compound having a hydrocarbon group (X). Note that when a carboxylic acid compound has the hydrocarbon group (X), the number of carbon atoms in the carboxyl group is not taken as part in the number of carbon atoms in the hydrocarbon group (X).

In a preferred embodiment, in the polyamideimide, the diamine or diisocyanate compound includes a diamine or diisocyanate compound having a hydrocarbon group (X) and a diamine or diisocyanate compound having an aromatic hydrocarbon group; and the carboxylic acid compound includes a carboxylic acid compound having an aromatic hydrocarbon group. In another preferred embodiment, in the polyamideimide, the diamine or diisocyanate compound includes a diamine or diisocyanate compound having an aromatic hydrocarbon group; and the carboxylic acid compound includes a carboxylic acid compound having a hydrocarbon group (X) and a carboxylic acid compound having an aromatic hydrocarbon group.

### (Hydrocarbon Group (X))

The hydrocarbon group (X) that a diamine or diisocyanate compound and a carboxylic acid compound can have includes at least one non-aromatic hydrocarbon group. In the hydrocarbon group (X), the total number of carbon atoms in the at least one non-aromatic hydrocarbon group is eight or more. When the hydrocarbon group (X) includes one non-aromatic hydrocarbon group, the total number of carbon atoms means the number of all carbon atoms included in the one non-aromatic hydrocarbon group. When the hydrocarbon group (X) includes two or more non-aromatic hydrocarbon groups, the total number of carbon atoms means the number of all carbon atoms included in the two or more non-aromatic hydrocarbon groups. The hydrocarbon group (X) may further include an optional group other than the non-aromatic hydrocarbon group. The hydrocarbon group (X) is, for example, a monovalent to tetravalent group, preferably a divalent to tetravalent group, and more preferably a divalent group.

The non-aromatic hydrocarbon group is, for example, a saturated aliphatic hydrocarbon group, an unsaturated aliphatic hydrocarbon group, a saturated alicyclic hydrocarbon group, an unsaturated alicyclic hydrocarbon group, or a group consisting of two or more selected from these. The saturated aliphatic hydrocarbon group may be a linear or branched. The unsaturated aliphatic hydrocarbon group may be a linear or branched. When the hydrocarbon group (X) includes two or more non-aromatic hydrocarbon groups, the two or more non-aromatic hydrocarbon groups may be the same or different from each other.

The number of carbon atoms in a saturated aliphatic hydrocarbon group is, for example, within a range from 1 to 50, from 2 to 40, from 3 to 30, from 4 to 20, or from 5 to 10. The saturated aliphatic hydrocarbon group is, for example, an atomic group obtained by removing one to four hydrogen atoms from a linear or branched alkane. Examples of the alkane include methane, ethane, propane, butane, pentane, hexane, heptane, octane, nonane, decane, undecane, dodecane, tridecane, tetradecane, pentadecane, hexadecane, heptadecane, octadecane, nonadecane, eicosane, heneicosane, docosane, tricosane, tetracosane, hexacosane, octacosane, triacontane, tetracontane, and pentacontane.

The number of carbon atoms in an unsaturated aliphatic hydrocarbon group is, for example, within a range from 2 to 50, from 2 to 40, from 3 to 30, from 4 to 20, or from 5 to 10. The number of carbon-carbon unsaturated bonds included in the unsaturated aliphatic hydrocarbon group is one or more, and may be, for example, five or less, four or less, three or less, or two or less. The unsaturated aliphatic hydrocarbon group may be an alkene including one carbon-carbon double bond, or an alkyne including one carbon-carbon triple bond. The unsaturated aliphatic hydrocarbon group may be, for example, an atomic group obtained by removing one to four hydrogen atoms from a linear or branched alkene, or an atomic group obtained by removing one to four hydrogen atoms from a linear or branched alkyne. Examples of alkenes include ethene, propene, butene, pentene, hexene, heptene, octene, nonene, decene, undecene, dodecene, tridecene, tetradecene, pentadecene, hexadecene, heptadecene, octadecene, nonadecene, eicosene, heneicosene, docosene, tricosene, tetracosene, pentacosene, hexacosene, heptacosene, octacosene, nonacosene, triacontene, tetracontene, and pentacontene. Examples of alkynes include ethyne, propyne, butyne, pentyne, hexyne, heptyne, octyne, nonyne, decyne, undecyne, dodecyne, tridecyne, tetradecyne, pentadecyne, hexadecyne, heptadecyne, octadecyne, nonadecyne, eicosyne, heneicosyne, docosyne, tricosyne, tetracosyne, pentacosyne, hexacosyne, heptacosyne, octacosyne, nonacosyne, triacontyne, tetracontyne, and pentacontyne.

The number of carbon atoms in the saturated alicyclic hydrocarbon group is, for example, within a range from 3 to 20, from 4 to 16, from 5 to 10, or from 6 to 8. The saturated alicyclic hydrocarbon group is, for example, an atomic group obtained by removing one to four hydrogen atoms from a cycloalkane. Examples of the cycloalkane include cyclopropane, cyclobutane, cyclopentane, cyclohexane, cycloheptane, cyclooctane, norbornane, decalin, bicyclobutane, bicyclohexane, bicyclooctane, spiropentane, spiroheptane, guadricyclane, and adamantane.

The number of carbon atoms in the unsaturated alicyclic hydrocarbon group is, for example, within a range from 4 to 20, from 5 to 10, or from 6 to 8. The number of carbon-carbon unsaturated bonds included in the unsaturated aliphatic hydrocarbon group is one or more, and may be, for example, five or less, four or less, three or less, or two or less. The unsaturated aliphatic hydrocarbon may be a cycloalkene including one carbon-carbon double bond, or a cycloalkyne including one carbon-carbon triple bond. The unsaturated alicyclic hydrocarbon group is, for example, an atomic group obtained by removing one to four hydrogen atoms from a cycloalkene, or an atomic group obtained by removing one to four hydrogen atoms from a cycloalkyne. Examples of the unsaturated alicyclic hydrocarbon include cyclobutene, cyclopentene, cyclopentadiene, cyclohexene, cyclohexadiene, cycloheptene, norbornene, norbornadiene, and bicyclooctadiene.

Examples of an optional group that can be included in the hydrocarbon group (X) include an aromatic hydrocarbon group, and a group containing a heteroatom.

The number of carbon atoms in the aromatic hydrocarbon group is, for example, within a range from 6 to 30, from 6 to 20, or from 6 to 10. The aromatic hydrocarbon group is, for example, an atomic group obtained by removing one to four hydrogen atoms from an aromatic hydrocarbon. Examples of the aromatic hydrocarbon include benzene, naphthalene, anthracene, pyrene, and pentane.

Examples of the group containing a heteroatom include a heterocyclic compound group, a linking group containing a heteroatom, and a substituent containing a heteroatom. The heterocyclic compound group is, an atomic group obtained by removing one to four hydrogen atoms from a non-aromatic heterocyclic compound, or an atomic group obtained by removing one to four hydrogen atoms from an aromatic heterocyclic compound. Examples of the non-aromatic heterocyclic compound include tetrahydrofuran, tetrahydrothiophene, and dioxane. Examples of the aromatic heterocyclic compound include pyridine, benzofuran, and benzothiophene. Examples of the linking group containing a heteroatom include an oxy group, a thio group, a sulfonyl group, a sulfinyl group, a carbonyl group, a carbonyloxy group, and an imino group. Examples of the substituent containing a heteroatom include a hydroxyl group, a mercapto group, a sulfo group, a sulfino group, a carboxyl group, a fluoro group, and a chloro group.

The total number of carbon atoms in at least one non-aromatic hydrocarbon group included in the hydrocarbon group (X) is eight or more. Examples are given below of the hydrocarbon group (X), and the total number of carbon atoms in at least one non-aromatic hydrocarbon group included in the hydrocarbon group (X). Examples of groups not corresponding with the hydrocarbon group (X) are given as reference examples. “*” represents a bonding position with another atom.

TABLE 1

| | | Number of |
|---|---|---|
| | Group | carbon atoms |
| Hydrocarbon group (X) | 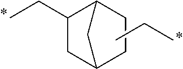 | 9 |
| | 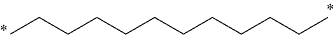 | 10 |
| | 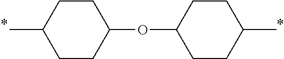 | 12 |
| | 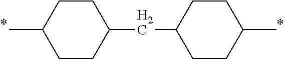 | 13 |
| | 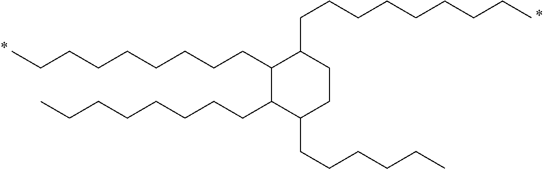 [SMILES: CCCCCCCCCC1CCC(CCCCCC)C(CCCCCCCC)C1CCCCCCCCC] | 36 |
| Reference example | 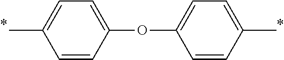 | 0 |
| | 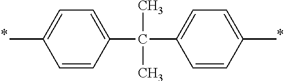 | 3 |
| | 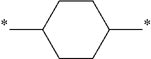 | 6 |

The total number of carbon atoms in the at least one non-aromatic hydrocarbon group included in the hydrocarbon group (X) is eight or more. The number of carbon atoms may be, for example, 12 or more, 16 or more, 20 or more, 24 or more, 28 or more, 32 or more, or 36 or more. The total number of carbon atoms in the at least one non-aromatic hydrocarbon group included in the hydrocarbon group (X) is, for example, 50 or less. The number of carbon atoms may be, for example, 48 or less, 44 or less, 40 or less, or 36 or less. When the total number of carbon atoms in the non-aromatic hydrocarbon group is eight or more, a polyamideimide having a low permittivity and a low dielectric loss tangent can be obtained. When the total number of carbon atoms in the non-aromatic hydrocarbon groups is 50 or less, a raw material monomer can be easily obtained, and a polyamideimide can be easily synthesized. Even if the polyamideimide has a group where the total number of carbon atoms in an aromatic hydrocarbon group is eight or more, a polyamideimide having a low permittivity and a low dielectric loss tangent cannot be obtained.

The hydrocarbon group (X) preferably includes a saturated aliphatic hydrocarbon group, and more preferably a linear saturated aliphatic hydrocarbon group where the number of carbon atoms is six or more (preferably the number of carbon atoms is eight or more). When the polyamideimide includes a structure including a linear saturated aliphatic hydrocarbon group where the number of carbon atoms is six or more, the permittivity tends to easily become lower, and the low dielectric loss tangent tends to easily become lower. By having a linear saturated aliphatic hydrocarbon group where the number of carbon atoms is six or more, it is thought that a polarity (dipole moment) in the polyamideimide molecule decreases, and the permittivity decreases. However, the present invention is not limited by this presumption.

The hydrocarbon group (X) preferably includes at least one selected from the group consisting of a saturated alicyclic hydrocarbon group and an unsaturated alicyclic hydrocarbon group; and more preferably includes a saturated alicyclic hydrocarbon group. When the polyamideimide includes at least one of a saturated alicyclic hydrocarbon group and an unsaturated alicyclic hydrocarbon group, the permittivity tends to be low more easily. The reason is presumed to be that the polyamideimide has an alicyclic structure, and thus the free volume increases. However, the present invention is not limited by this presumption.

The hydrocarbon group (X) preferably includes at least one selected from the group consisting of a group represented by formula (G1) below, a group represented by formula (G2) below, a group represented by formula (G3) below, a group represented by formula (G4) below, and a group represented by formula (G5) below. In formulas (G1) to (G5), “*” represents a bonding position with another atom.

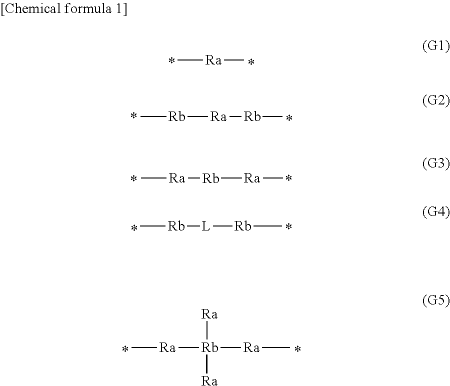

In formulas, each Ra independently represents a linear or branched saturated aliphatic hydrocarbon group, or a linear or branched unsaturated aliphatic hydrocarbon group. Each Rb independently represents a saturated alicyclic hydrocarbon group, or an unsaturated alicyclic hydrocarbon group. L represents a single bond or a linking group containing a heteroatom. Ra and Rb may or may not each independently have a substituent.

In a preferred embodiment, the polyamideimide includes a structure derived from a compound having a group represented by formula (G1) (for example, the number of carbon atoms in Ra is eight or more). Examples of such compounds include polymethylenediamine, polymethylene diisocyanate, and polymethylene dicarboxylic acid.

In another preferred embodiment, the polyamideimide includes at least one selected from the group consisting of a structure derived from a compound having a group represented by formula (G2) (for example, the number of carbon atoms in each Rb is independently six or more, and preferably eight or more), a structure derived from a compound having a group represented by formula (G3) (for example, the number of carbon atoms in each Ra is independently six or more, and preferably eight or more), and a structure derived from a compound having a group represented by formula (G5) (for example, the number of carbon atoms in Rb is six, and the number of carbon atoms in each Ra is independently six or more, and preferably the number of carbon atoms in Rb is six, and the number of carbon atoms in each Ra is independently six or more). Examples of these compounds include a dimer acid, a hydrogenated dimer acid, a dimer diamine, a hydrogenated dimer diamine, a dimer diisocyanate, and a hydrogenated dimer diisocyanate.

### (Aromatic Hydrocarbon Group)

The number of carbon atoms in an aromatic hydrocarbon group that a diamine or diisocyanate compound and a carboxylic acid compound can have is, for example, within a range from 6 to 30, from 6 to 20, or from 6 to 10. The aromatic hydrocarbon group is, for example, an atomic group obtained by removing one to four hydrogen atoms from an aromatic hydrocarbon. Examples of the aromatic hydrocarbon include benzene, naphthalene, anthracene, pyrene, and pentane. When the polyamideimide includes an aromatic hydrocarbon group, good heat resistance and good mechanical properties are easily obtained.

### (Diamine or Diisocyanate Compound Having a Hydrocarbon Group (X))

Examples of the diamine or diisocyanate compound having a hydrocarbon group (X) include a diamine having the hydrocarbon group (X) described above and two amino groups bonded to the hydrocarbon group (X), or a diisocyanate having the hydrocarbon group (X) described above and two isocyanate groups bonded to the hydrocarbon group (X).

Specific examples of the diamine having a hydrocarbon group (X) include the following.

Diamines which have a saturated aliphatic hydrocarbon group and where the number of carbon atoms is eight or more, such as 1,8-diaminooctane, 1,9-diaminononane, 1,10-diaminodecane, 1,11-diaminoundecane, 1,12-diaminododecane, 1,14-diaminotetradecane, and 1,16-diaminohexadecane;

Diamines which have an unsaturated aliphatic hydrocarbon group and where the number of carbon atoms is eight or more, such as 1,8-diaminooctene, 1,9-diaminononene, 1,10-diaminodecene, 1,11-diaminoundecene, 1,12-diaminododecene, 1,14-diaminotetradecene, and 1,16-diaminohexadecene;

Diamines which have a saturated alicyclic hydrocarbon group and where the number of carbon atoms is eight or more, such as isophoronediamine, bis(aminomethyl) norbornane, 1,3-diaminoadamantane, 1,3-bis(aminomethyl)cyclohexane, 1,4-bis(aminomethyl)cyclohexane, 4,4′-diaminodicyclohexylmethane, 3,3′-dimethyl-4,4′-diaminodicyclohexylmethane, 3,3′-diethyl-4,4′-diaminodicyclohexylmethane, 3,3′,5,5′-tetramethyl-4,4′-diaminodicyclohexylmethane, 3,3′,5,5′-tetraethyl-4,4′-diaminodicyclohexylmethane, 3,5-diethyl-3′,5′-dimethyl-4,4′-diaminodicyclohexylmethane, 4,4′-diaminodicyclohexyl ether, 3,3′-dimethyl-4,4′-diaminodicyclohexyl ether, 3,3′-diethyl-4,4′-diaminodicyclohexyl ether, 3,3′,5,5′-tetramethyl-4,4′-diaminodicyclohexyl ether, 3,3′,5,5′-tetraethyl-4,4′-diaminodicyclohexyl ether, 3,5-diethyl-3′,5′-dimethyl-4,4′-diaminodicyclohexyl ether, 2,2-bis(4-aminocyclohexyl) propane, 2,2-bis(3-methyl-4-aminocyclohexyl) propane, 2,2-bis(3-ethyl-4-aminocyclohexyl) propane, 2,2-bis(3,5-dimethyl-4-aminocyclohexyl) propane, 2,2-bis(3,5-diethyl-4-aminocyclohexyl) propane, and 2,2-(3,5-diethyl-3′,5′-dimethyl-4,4′-diaminodicyclohexyl) propane;

Diamines which have an unsaturated alicyclic hydrocarbon group and where the number of carbon atoms is eight or more, such as bis(aminomethyl) norbornene, and 4,4′-diaminodicyclohexenylmethane;

Dimer diamines which are derived from dimers (also referred to as dimer acid) of unsaturated fatty acids, such as: monounsaturated fatty acids, such as crotonic acid, myristoleic acid, palmitoleic acid, sapienoic acid, oleic acid, elaidic acid, vaccenic acid, gadoleic acid, eicosenoic acid, erucic acid, and nervonic acid; diunsaturated fatty acids, such as linoleic acid, eicosadienoic acid, and docosadienoic acid; and triunsaturated fatty acids, such as linolenic acid, pinolenic acid, eleostearic acid, mead acid, dihomo-γ-linolenic acid, and eicosatrienoic acid, and where the number of carbon atoms is eight or more; and

Hydrogenated dimer diamines which are compounds in which a carbon-carbon double bond in the molecule of the dimer diamines is hydrogenated, and where the number of carbon atoms is eight or more

Specific examples of the diisocyanate having a hydrocarbon group (X) include compounds having the same structures as the compounds described as specific examples of the above diamine, except that an amino group is replaced with an isocyanate group.

### (Carboxylic Acid Compound Having a Hydrocarbon Group (X))

Examples of the carboxylic acid compound having a hydrocarbon group (X) include a tricarboxylic anhydride having the hydrocarbon group (X) described above, and one carboxyl group and one acid anhydride group bonded to the hydrocarbon group (X); and a dicarboxylic acid having the hydrocarbon group (X) described above, and two carboxyl groups bonded to the hydrocarbon group (X).

Further, specific examples of the carboxylic acid compound having a hydrocarbon group (X) include the following.

Aliphatic tricarboxylic anhydrides, such as a decahydronaphthalene tricarboxylic anhydride, 3,4,4′-bicyclohexane tricarboxylic anhydride, 2,3,2′-bicyclohexane tricarboxylic anhydride, and 3,4,4′-bicyclohexane methane tricarboxylic anhydride; and

Dicarboxylic acids having the same structures as the compounds described as specific examples of the above diamine having a hydrocarbon group (X) except that an amino group is replaced with a carboxyl group

### (Diamine or Diisocyanate Compound Having an Aromatic Hydrocarbon Group)

Examples of the diamine or diisocyanate compound having an aromatic hydrocarbon group include a diamine having one or more aromatic hydrocarbon groups described above and two amino groups, and a diisocyanate having one or more aromatic hydrocarbon groups described above and two isocyanate groups.

Specific examples of the diamine having an aromatic hydrocarbon group include the following.

Diamines having an aromatic hydrocarbon group, such as a 1,4-phenylenediamine, a 1,2-phenylenediamine, a 1,3-phenylenediamine, 4,4′-(biphenyl-2,5-diylbisoxy)bisaniline, 4,4′-diaminodiphenylmethane, 4,4′-diaminodiphenyl ether, 3,4′-diaminodiphenyl ether, 1,4-bis(4-aminophenoxy)benzene, 1,3-bis(4-aminophenoxy)benzene, 2,2-bis(4-(4-aminophenoxy)phenyl) propane, bis(4-(4-aminophenoxy)phenyl) sulfone, bis(4-(3-aminophenoxy)phenyl) sulfone, 1,3-bis(4-aminophenoxy) neopentane, 4,4′-diamino-3,3′-dimethylbiphenyl, 4,4′-diamino-2,2′-dimethylbiphenyl, 4,4′-bis(4-aminophenoxy) biphenyl, 4,4′-diamino-3,3′-dihydroxybiphenyl, bis(4-amino-3-carboxyphenyl) methane, 4,4′-diaminodiphenyl sulfone, 3,3′-diaminodiphenyl sulfone, 4,4′-diaminodiphenyl sulfide, N-(4-aminophenoxy)-4-aminobenzamine, 2,2′-bis(trifluoromethyl)-4,4′-diaminobiphenyl, bis(3-aminophenyl) sulfone, norbornanediamine, 4,4′-diamino-2-(trifluoromethyl)diphenyl ether, 5-trifluoromethyl-1,3-benzenediamine, 2,2-bis(4-(4-aminophenoxy)phenyl) hexafluoropropane, 4,4′-diamino-2,2′-bis(trifluoromethyl) biphenyl, 2,2-bis[4-{4-amino-2-(trifluoromethyl) phenoxy}phenyl] hexafluoropropane, 2-trifluoromethyl-p-phenylenediamine, 2,2-bis(3-amino-4-methylphenyl) hexafluoropropane, 4,4′-(9-fluorenylidene)dianiline, 2,7-diaminofluorene, and 1,5-diaminonaphthalene (however, the total number of carbon atoms included in the non-aromatic hydrocarbon group included in the diamine is within a range from 0 to 7)

Specific examples of the diisocyanate having an aromatic hydrocarbon group include compounds having the same structures as the compounds described as specific examples of the above diamine except that an amino group is replaced with an isocyanate group.

### (Carboxylic Acid Compound Having an Aromatic Hydrocarbon Group)

Examples of the carboxylic acid compound having an aromatic hydrocarbon group include a dicarboxylic acid having an aromatic hydrocarbon group described above and two carboxyl groups, and a tricarboxylic anhydride having an aromatic hydrocarbon group described above, one carboxyl group, and one acid anhydride group.

Further, specific examples of the carboxylic acid compound having an aromatic hydrocarbon group include the following.

Aromatic tricarboxylic acids, such as a trimellitic anhydride, a naphthalenetricarboxylic anhydride, a 3,4,4′-biphenyltricarboxylic anhydride, a 2,3,2′-biphenyltricarboxylic anhydride, a 3,4,4′-biphenylmethane tricarboxylic anhydride, a 3,4,4′-biphenyl ether tricarboxylic anhydride, a 3,4,4′-benzophenone tricarboxylic anhydride, and a 3,4,4′-biphenylsulfone tricarboxylic anhydride; and

Dicarboxylic acids having the same structure as the compounds described as specific examples of the diamine having an aromatic hydrocarbon group described above except that an amino group is replaced with a carboxyl group

### (Optional Structure)

The polyamideimide can have an optional structure other than the structure derived from a compound including at least one selected from the group consisting of a diamine and a diisocyanate, and the structure derived from a carboxylic acid compound including at least a tricarboxylic anhydride. Examples of the optional structure include a structure derived from a trifunctional or higher amine or isocyanate, and a structure derived from a monofunctional amine or isocyanate. The carboxylic acid compound can include an optional compound other than the tricarboxylic anhydride. Examples of the optional compound include a dicarboxylic acid, a dicarboxylic anhydride, a tricarboxylic acid, a tetracarboxylic acid, and a tetracarboxylic anhydride.

### (Production Method)

The polyamideimide can be obtained by reacting at least a diamine or diisocyanate compound with a carboxylic acid compound. For the reaction, only one type of each of these compounds may be used, or two or more types of each of these compounds may be used in combination. Any other compound may be reacted.

Synthesis conditions of the polyamideimide are various and cannot be specified, but the synthesis can be performed, for example, at a temperature of 80° C. to 180° C. The synthesis is preferably performed under an atmosphere of nitrogen or the like in order to reduce the influence of moisture in the air. The synthesized polyamideimide is obtained, for example, as a polyamideimide containing liquid in which the polyamideimide is dissolved in a solvent used for the reaction.

The solvent is not particularly limited, but examples include: polar solvents, such as N-methyl-2 pyrrolidone (NMP), N-ethyl-2-pyrrolidone (NEP), γ-butyrolactone (GBL), 3-methoxy-N, N-dimethylpropanamide (MPA), N,N′-dimethylformamide, N,N′-dimethylpropylurea[1,3-dimethyl-3,4,5,6-tetrahydropyridimine-2 (1H)-one], dimethyl sulfoxide, diethylene glycol dimethyl ether, triethylene glycol dimethyl ether, and sulfolane; aromatic hydrocarbon solvents, such as xylene and toluene; and ketone-based solvents, such as methyl ethyl ketone and methyl isobutyl ketone. The solvent preferably includes at least one selected from the group consisting of N-methyl-2-pyrrolidone (NMP), N-ethyl-2-pyrrolidone (NEP), γ-butyrolactone (GBL), and 3-methoxy-N,N-dimethylpropanamide (MPA), and more preferably includes at least one selected from the group consisting of N-ethyl-2-pyrrolidone (NEP), γ-butyrolactone (GBL), and 3-methoxy-N,N-dimethylpropanamide (MPA).

The amount of solvent used during the reaction is preferably within a range from 100 to 300 parts by mass, more preferably from 150 to 250 parts by mass, relative to 100 parts by mass of the total amount of the carboxylic acid compound and the diamine or diisocyanate compound. When the amount of solvent used is 100 parts by mass or more, reactions involving foaming tends to be easily prevented. When the amount of solvent used is 300 parts by mass or less, the synthesis time tends to be prevented from becoming too long, and the concentration of the polyamideimide included in the solution obtained after the synthesis tends to be sufficient.

It is preferable that the carboxylic acid compound and the diamine or diisocyanate compound be reacted so that the ratio of the number of moles of the amino group and the isocyanate group to the total number of moles of the functional groups including the carboxyl group, the acid anhydride group, and a reactive hydroxyl group if optionally presents is preferably within a range from 0.6 to 1.4, more preferably from 0.7 to 1.3, and even more preferably from 0.8 to 1.2. When the ratio is 0.6 or more, the molecular weight of the polyamideimide tends to be easily increased. When the ratio is 1.4 or less, it is possible to prevent reactions involving foaming from becoming intense, and the amount of unreacted substances remaining from increasing, and the polyamideimide tends to be easily obtained having good stability.

(Content Percentages, Etc. Of Structure Derived from Compound Having a Hydrocarbon Group (X))

The content of a structure derived from a compound having a hydrocarbon group (X), and is included in the polyamideimide is, for example, within a range from 5% to 50% by mole, from 7% to 30% by mole, or from 8% to 20% by mole, relative to the content of the structure derived from the diamine or diisocyanate compound and the structure derived from the carboxylic acid compound (that is, when the total content of the structure derived from the diamine or diisocyanate compound and the structure derived from the carboxylic acid compound is 100% by mole). The content of a structure derived from a compound having an aromatic hydrocarbon group, and is included in the polyamideimide is, for example, within a range from 50% to 95% by mole, from 70% to 93% by mole, or from 80% to 92% by mole, relative to the content of the structure derived from the diamine or diisocyanate compound and the structure derived from the carboxylic acid compound.

In the polyamideimide, when the diamine or diisocyanate compound includes a diamine or diisocyanate compound having a hydrocarbon group (X) and a diamine or diisocyanate compound having an aromatic hydrocarbon group, and the carboxylic acid compound includes a carboxylic acid compound having an aromatic hydrocarbon group, the content of the structure derived from the diamine or diisocyanate compound having a hydrocarbon group (X) is, for example, within a range from 5% to 50% by mole, from 8% to 40% by mole, or from 10% to 30% by mole, relative to the content of the structure derived from the diamine or diisocyanate compound (that is, when the content of the structure derived from the diamine or diisocyanate compound is 100% by mole). The content of the structure derived from the diamine or diisocyanate compound having an aromatic hydrocarbon group is, for example, within a range from 50% to 95% by mole, from 60% to 92% by mole, or from 70% to 90% by mole, relative to the content of the structure derived from the diamine or diisocyanate compound.

In the polyamideimide, when the diamine or diisocyanate compound includes a diamine or diisocyanate compound having an aromatic hydrocarbon group, and the carboxylic acid compound includes a carboxylic acid compound having a hydrocarbon group (X) and a carboxylic acid compound having an aromatic hydrocarbon group, the content of the structure derived from the carboxylic acid compound having a hydrocarbon group (X) is, for example, within a range from 10% to 60% by mole, from 15% to 50% by mole, or from 20% to 40% by mole, relative to the content of the structure derived from the carboxylic acid compound (that is, when the content of the structure derived from the carboxylic acid compound is 100% by mole). The content of the structure derived from the carboxylic acid compound having an aromatic hydrocarbon group is, for example, within a range from 40% to 90% by mole, from 50% to 85% by mole, or 60% to 80% by mole, relative to the content of the structure derived from the carboxylic acid compound.

In the polyamideimide, the content of a structure derived from a tricarboxylic anhydride is, for example, more than 50% by mole, 60% by mole or more, or 65% by mole or more, relative to the content of the structure derived from the carboxylic acid compound (that is, when the content of the structure derived from the carboxylic acid compound is 100% by mole). The upper limit may be 100% by mole, but when a structure derived from another carboxylic acid, such as a dicarboxylic acid, is included, it is, for example, 90% by mole or less, 80% by mole or less, or 75% by mole or less. In the polyamideimide, when the structure derived from the dicarboxylic acid is included, the content of the structure derived from the dicarboxylic acid is, for example, less than 50% by mole, 40% by mole or less, or 35% by mole or less.

In some embodiments, the polyamideimide includes a structure derived from a diamine or diisocyanate compound, and a structure derived from a carboxylic acid compound; the diamine or diisocyanate compound includes a dimer diamine where the number of carbon atoms is eight or more or a hydrogenated dimer diamine where the number of carbon atoms is eight or more; and the carboxylic acid compound includes a tricarboxylic anhydride having an aromatic hydrocarbon group. The compound may further include a diamine having an aromatic hydrocarbon group.

In some embodiments, the polyamideimide includes a structure derived from a diamine or diisocyanate compound and a structure derived from a carboxylic acid compound; the carboxylic acid compound includes a dicarboxylic acid having a linear saturated aliphatic hydrocarbon group where the number of carbon atoms is eight or more; and the diamine or diisocyanate compound includes a diamine having an aromatic hydrocarbon group. The carboxylic acid compound may further include a tricarboxylic anhydride having an aromatic hydrocarbon group.

### (Number Average Molecular Weight)

The number average molecular weight of the polyamideimide is preferably within a range from 3,000 to 100,000. When the number average molecular weight is 3,000 or more, various properties, such as strength, tend to be improved. The number average molecular weight of the polyamideimide may be 5,000 or more, 8,000 or more, 15,000 or more, or 20,000 or more. When the number average molecular weight is 100,000 or less, excellent coating properties tend to be obtained. The number average molecular weight of the polyamideimide may be 80,000 or less, 50,000 or less, 35,000 or less, 30,000 or less, or 27,000 or less.

The relative permittivity (10 GHz) of the polyamideimide is, for example, 4.0 or less, 3.6 or less, 3.3 or less, or 3.1 or less, from the viewpoint of obtaining excellent insulating properties. The relative permittivity of the polyamideimide is not particularly limited, but is, for example, 2.0 or more from the viewpoint of preventing decreases in heat resistance, tensile strength, and tensile modulus.

The dielectric loss tangent (10 GHz) of the polyamideimide is, for example, 0.020 or less, 0.015 or less, or 0.010 or less, from the viewpoint of suppressing transmission loss. The dielectric loss tangent of the polyamideimide is not particularly limited, but may be 0.0001 or more, or may be 0.0005 or more.

The tensile strength of the polyamideimide is, for example, 30 MPa or more, 50 MPa or more, or 80 MPa or more, from the viewpoint of strength of a compact. The tensile strength of the polyamideimide is not particularly limited, but is, for example, 400 MPa or less, 300 MPa or less, or 250 MPa or less, from the viewpoint of stretchability during processing.

The elongation at break of the polyamideimide is, for example, 3% or more, 5% or more, or 8% or more, from the viewpoint of flexibility of a compact. The elongation at break may be 20% or more, 30% or more, or 50% or more. The elongation at break of the polyamideimide is not particularly limited, but is, for example, 300% or less, 200% or less, or 100% or less.

The tensile modulus of the polyamideimide is, for example, 0.5 GPa or more, 0.7 GPa or more, 1.0 GPa or more, or 1.5 GPa or more, from the viewpoint of strength of a compact. The tensile modulus of the polyamideimide is, for example, 7 GPa or less, 6 GPa or less, or 5 GPa or less, from the viewpoint of flexibility of a compact.

The glass transition temperature (Tg) of the polyamideimide is, for example, 120° C. or more, 140° C. or more, or 160° C. or more, from the viewpoint of heat resistance of a compact. The upper limit is not particularly limited, but is, for example, 350° C. or less, or 300° C. or less.

In the present disclosure, the relative permittivity, dielectric loss tangent, tensile strength, elongation at break, tensile modulus, and glass transition temperature (Tg) of the polyamideimide can be found by producing a polyamideimide film according to a method described in examples, and by measuring the produced polyamideimide film according to a method described in the examples.

### [Applications]

The polyamideimide can be used in various electronic components and mechanical components, for example, displays, solar cells, touch panels, organic EL lighting, printed boards, and the like.

### <Polyamideimide Containing Liquid>

A polyamideimide containing liquid according to an embodiment of the present invention contains the polyamideimide and a solvent. An example of the solvent is a solvent during the reaction described above which can be used for the synthesis of the polyamideimide. The solvent preferably includes at least one selected from the group consisting of N-methyl-2-pyrrolidone (NMP), N-ethyl-2-pyrrolidone (NEP), γ-butyrolactone (GBL), and 3-methoxy-N,N-dimethylpropanamide (MPA), and more preferably includes at least one selected from the group consisting of N-ethyl-2-pyrrolidone (NEP), γ-butyrolactone (GBL), and 3-methoxy-N,N-dimethylpropanamide (MPA).

The amount contained of the polyamideimide in the polyamideimide containing liquid can be set in a range suitable for an application of the polyamideimide containing liquid. The amount contained of the polyamideimide is, for example, within a range from 5% to 60% by mass, from 10% to 50% by mass, or from 20% to 45% by mass, relative to the mass of the polyamideimide containing liquid.

The polyamideimide containing liquid can be preferably used as a composition for an insulator, a composition for a heat-resistant insulator, or a composition for a printed board, or for preparation of these compositions. The composition may further contain an optional component, such as a polyamide, a polyethersulfone, an acrylic polymer, an epoxy compound, an isocyanate compound, a melamine compound, a filler, an antifoaming agent, a preservative, or a surfactant. The composition can be produced, for example, using a method of mixing the polyamideimide containing liquid with an optional component used as necessary, and stirring the mixture.

### <Polyamideimide Film>

A polyamideimide film according to an embodiment of the present invention is obtained by using the polyamideimide according to the embodiment described above, or the polyamideimide containing liquid according to the embodiment described above, or may include the polyamideimide film according to the embodiment described above. The polyamideimide film according to the embodiment of the present invention has excellent insulating properties.

The polyamideimide film can be obtained, for example, by applying the polyamideimide containing liquid on a substrate, such as a glass plate, drying it, and then heating it. The drying temperature may be, for example, within a range from 50° C. to 100° C. The heating temperature may be, for example, within a range from 230° C. to 350° C. The film thickness of the polyamideimide film may be appropriately set according to applications, for example, within a range from 5 to 1,000 μm, from 10 to 100 μm, or from 20 to 50 μm.

### <Printed Board>

A printed board according to an embodiment of the present invention is obtained by using the polyamideimide according to the embodiment described above, or the polyamideimide containing liquid according to the embodiment described above, or includes the polyamideimide film according to the embodiment described above. The printed board of an embodiment of the present invention has low transmission loss and excellent heat resistance.

Examples of the printed board include a printed wiring board and a printed circuit board. Examples of the printed board include a flexible board and a rigid board. Examples of the printed board include a single-sided board, a double-sided board, and a multilayer board. For example, a substrate material, a protective film, an insulating layer, and the like of these boards are obtained by using the polyamideimide or the polyamideimide containing liquid, or includes the polyamideimide film.

An example of the flexible board is a board including a base film that is obtained by using the polyamideimide or the polyamideimide containing liquid or includes the polyamideimide film. Another example of the flexible board is a board including a base film and a heat-resistant insulating layer formed on the base film, where at least the heat-resistant insulating layer is obtained by using the polyamideimide or the polyamideimide containing liquid, or includes the polyamideimide film.

Examples of embodiments are listed below. The present invention is not limited to the following embodiments.

(1) A polyamideimide, including:
a structure derived from a compound including at least one selected from the group consisting of a diamine and a diisocyanate, and a structure derived from a carboxylic acid compound including at least a tricarboxylic anhydride, wherein
at least one selected from the compound and the carboxylic acid compound includes a compound having a group that includes at least one non-aromatic hydrocarbon group, where a total number of carbon atoms in the at least one non-aromatic hydrocarbon group is eight or more, and
at least one selected from the compound and the carboxylic acid compound includes a compound having an aromatic hydrocarbon group.
   (2) The polyamideimide according to (1) above, wherein the carboxylic acid compound further includes a dicarboxylic acid.
   (3) The polyamideimide according to (1) or (2) above, wherein the group that includes the at least one non-aromatic hydrocarbon group, where a total number of carbon atoms in the at least one non-aromatic hydrocarbon group is eight or more, includes a saturated aliphatic hydrocarbon group where a number of carbon atoms is eight or more.
   (4) The polyamideimide according to any one of (1) to (3) above, wherein the number of carbon atoms is 28 or more.
   (5) The polyamideimide according to any one of (1) to (4) above, wherein tensile strength is 80 MPa or more.
   (6) The polyamideimide according to any one of (1) to (5) above, having elongation at break of 8% or more.
   (7) The polyamideimide according to any one of (1) to (6) above, having tensile modulus of 1.5 GPa or more.
   (8) The polyamideimide according to any one of (1) to (7) above, having a permittivity at 10 GHz of 3.6 or less.
   (9) The polyamideimide according to any one of (1) to (8) above, having a dielectric loss tangent at 10 GHz of 0.015 or less.
   (10) The polyamideimide according to any one of (1) to (9) above, wherein
the compound includes a dimer diamine where a number of carbon atoms is eight or more, or a hydrogenated dimer diamine where a number of carbon atoms is eight or more, and
the carboxylic acid compound includes a tricarboxylic anhydride having an aromatic hydrocarbon group.
   (11) The polyamideimide according to (10) above, wherein the compound further includes a diamine having an aromatic hydrocarbon group.
   (12) The polyamideimide according to any one of claims 1 to 9 above, wherein
the carboxylic acid compound includes a dicarboxylic acid having a linear saturated aliphatic hydrocarbon group where a number of carbon atoms is eight or more, and
the compound includes a diamine having an aromatic hydrocarbon group.

(13) The polyamideimide according to (12) above, wherein the carboxylic acid compound further includes a tricarboxylic anhydride having an aromatic hydrocarbon group.

(14) A polyamideimide containing liquid, including: the polyamideimide according to any one of (1) to (13) above, and a solvent.
(15) A polyamideimide film, obtained by using the polyamideimide according to any one of (1) to (13) above, or the polyamideimide containing liquid according to (14) above.
(16) A printed board, obtained by using the polyamideimide according to any one of (1) to (13) above, or the polyamideimide containing liquid according to (14) above.

The disclosure of the present application relates to the subject matter described in JP 2022-090058 filed on Jun. 2, 2022, the entire disclosed contents of which are incorporated herein by reference.

### EXAMPLES

Embodiments of the present invention will be specifically described with reference to examples. Embodiments of the present invention are not limited to the following examples.

### Example 1

### (Preparation of Polyamideimide)

An amount of 19.2 g of trimellitic anhydride (TMAC), 20.0 g of 4,4′-diphenylmethane diisocyanate (MDI), 10.7 g of a dimer diamine (DDA) (having the hydrocarbon groups (X) with 36 carbon atoms, “PRIAMINE1075”, Croda Japan K.K.), and 60.0 g of N-methyl-2-pyrrolidone (NMP) were put into a flask equipped with a thermometer, a stirrer, and a condenser, and temperature was gradually raised to 130° C. over 2 hours while stirring in a stream of dry nitrogen. While paying attention to possible rapid foaming of carbon dioxide caused by the reaction, the temperature was maintained at 130° C., heating was continued as it was for 6 hours, and the reaction was stopped to obtain a polyamideimide solution. The number average molecular weight of the obtained polyamideimide was 32,000. The number average molecular weight was determined using the following method. PRIAMINE1075 used includes a dimer diamine represented by a structural formula below.

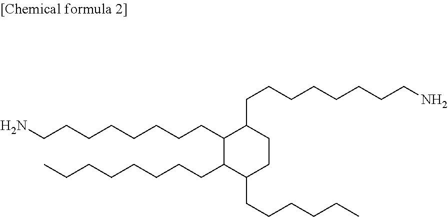 [SMILES: CCCCCCCCC1C(CCCCCC)CCC(CCCCCCCCN)C1CCCCCCCCN]

### (Number Average Molecular Weight)

The number average molecular weight (Mn) was determined by measuring by gel permeation chromatography (GPC) and converting using a standard polystyrene calibration curve. The calibration curve was approximated by a cubic equation using five sample sets (TSK standard POLYSTYRENE, manufactured by Tosoh Corporation) of standard polystyrene. The conditions of GPC are as follows.
GPC equipment: high-speed GPC equipment HLC-8320GPC (manufactured by Tosoh Corporation)
Detector: Ultraviolet absorption detector UV-8320 (manufactured by Tosoh Corporation)
Column: Gelpack GL-S300MDT-5 (total 2 pieces) (manufactured by Showa Denko Materials Co., Ltd.)
Eluent: THF/DMF=1/1 (volume ratio)+LiBr (0.06 mol/L)+H₃PO₄ (0.06 mol/L)
Flow rate: 1 mL/min
Column size: 8 mm I.D.×300 mm
Sample concentration: 5 mg/l mL
Injection volume: 5 μL
Measurement temperature: 40° C.

### (Production of Polyamideimide Film)

The obtained polyamideimide solution was applied to a glass substrate to form a coating film. The coating film was dried by heating at 80° C. for 30 minutes, and then heated at 270° C. for 30 minutes to produce a polyamideimide film having a film thickness of 20 μm. The polyamideimide film was peeled off from the glass substrate and used for various evaluations.

### Example 2, and Comparative Examples 1 and 2

Polyamideimide solutions were obtained in the same manner as in example 1 except that the diamine compound and/or the diisocyanate compound, and the acid component were change to those listed in table 2. The number average molecular weight of the polyamideimide is listed in table 2. Polyamideimide films were produced in the same manner as in example 1 using the obtained polyamideimide solutions, and were used for various evaluations. In table 2, SEBAC means a sebacic acid (having the hydrocarbon group (X) where the number of carbon atoms is eight), and TODI means 3,3′-dimethylbiphenyl-4,4′-diyl diisocyanate.

### <Evaluation of Film>

Properties of films produced using the varnishes of examples 1 and 2, and comparative examples 1 and 2 were evaluated according to the following method. Table 2 shows the evaluation results.

### (Tensile Strength, Tensile Modulus, and Elongation at Break)

The polyamideimide film was cut into a size of 10 mm in width and 60 mm in length to produce a test specimen. A tensile test was performed under the following measurement conditions, and the maximum tensile stress applied during the tensile test was defined as tensile strength (MPa). Elongation at break (%) was calculated by dividing elongation of the test specimen until break by a chuck distance of 20 mm. Young's modulus (MPa) was calculated from a slope of an elastic deformation region at the initial stage of stress rise, and the obtained value was defined as tensile modulus (MPa). Note that in the table, values (GPa) obtained by converting the obtained values (MPa) were listed. Other detailed conditions and calculation methods were performed in accordance with the international standard ISO 5271 (1993).
Equipment name: “Autograph AGS-100NG” manufactured by SHIMADZU CORPORATION
Test speed: 5 mm/min
Distance between chucks: 20 mm
Specimen size: width 10 mm, length 60 mm
Set temperature: room temperature (25° C.)

### (Glass Transition Temperature)

The polyamideimide film was cut into 4 mm in width and 25 mm in length to produce a test specimen. A thermomechanical analyzer (“TMA7100” manufactured by Hitachi High-Tech Science Corporation) was used for measurement. The test specimen was heated from room temperature to 350° C. at a rate of 10° C./min using a tension method with a chuck distance of 10 mm and a load of 10 g, and a temperature corresponding with an inflection point of a linear thermal expansion coefficient curve was defined as the glass transition temperature (° C.).

### (Relative Permittivity and Dielectric Loss Tangent)

The polyamideimide film was cut into a size of 60 mm×60 mm, dried at 125° C. for 1 hour, and then measurement was performed. The permittivity properties (relative permittivity Dk and dielectric loss tangent Df) of the film were measured using a cavity resonator method (TE mode). “MS46122B” manufactured by ANRITSU CORPORATION was used for the measurement. Conditions were set at a frequency of 10 GHz and a measurement temperature of 25° C.

TABLE 2

| | | | | | Comparative | Comparative |
|---|---|---|---|---|---|---|
| Items | | Units | Example 1 | Example 2 | example 1 | example 2 |
| Composition | MDI | (mol ratio) | 0.8 | 1.0 | 0.3 | 1.0 |
| (mol ratio) | DDA | (mol ratio) | 0.2 | — | — | — |
| | TODI | (mol ratio) | — | — | 0.7 | — |
| | TMAC | (mol ratio) | 1.0 | 0.7 | 1.0 | 1.0 |
| | SEBAC | (mol ratio) | — | 0.3 | — | — |
| Composition | MDI | g | 20.0 | 25 | 7.5 | 25 |
| (g) | DDA | g | 10.7 | — | — | — |
| | TODI | g | — | — | 18.5 | — |
| | TMAC | g | 19.2 | 13.4 | 19.2 | 19.2 |
| | SEBAC | g | — | 6.1 | — | — |
| Molecular | Number average | — | 32000 | 26000 | 25000 | 18000 |
| weight | molecular weight | | | | | |
| Mechanical | Tensile strength | MPa | 90 | 100 | 200 | 110 |
| properties | Elongation at break | % | 89 | 33 | 28 | 22 |
| | Tensile modulus | GPa | 1.8 | 2.1 | 5.7 | 3.0 |
| Thermal | Glass transition | ° C. | 190 | 280 | 320 | 290 |
| properties | temperature | | | | | |
| Dielectric | Relative permittivity | — | 3.0 | 3.3 | 3.5 | 3.4 |
| properties | (10 GHz) | | | | | |
| | Dielectric loss tangent | — | 0.006 | 0.013 | 0.008 | 0.014 |
| | (10 GHz) | | | | | |

1. A polyamideimide, comprising:
a structure derived from a compound including at least one selected from the group consisting of a diamine and a diisocyanate, and a structure derived from a carboxylic acid compound including at least a tricarboxylic anhydride, wherein
at least one selected from the compound and the carboxylic acid compound includes a compound having a group that includes at least one non-aromatic hydrocarbon group, where a total number of carbon atoms in the at least one non-aromatic hydrocarbon group is eight or more, and
at least one selected from the compound and the carboxylic acid compound includes a compound having an aromatic hydrocarbon group.

2. The polyamideimide according to claim 1, wherein the carboxylic acid compound further includes a dicarboxylic acid.

3. The polyamideimide according to claim 1, wherein the group that includes at least one non-aromatic hydrocarbon group, where a total number of carbon atoms in the at least one non-aromatic hydrocarbon group is eight or more, includes a saturated aliphatic hydrocarbon group where a number of carbon atoms is eight or more.

4. The polyamideimide according to claim 1, wherein the number of carbon atoms is 28 or more.

5. The polyamideimide according to claim 1, having a tensile strength of 80 MPa or more.

6. The polyamideimide according to claim 1, having an elongation at break of 8% or more.

7. The polyamideimide according to claim 1, having a tensile modulus of 1.5 GPa or more.

8. The polyamideimide according to claim 1, having a relative permittivity at 10 GHz of 3.6 or less.

9. The polyamideimide according to claim 1, having a dielectric loss tangent at 10 GHz of 0.015 or less.

10. The polyamideimide according to claim 1, wherein
the compound includes a dimer diamine where a number of carbon atoms is eight or more, or a hydrogenated dimer diamine where a number of carbon atoms is eight or more, and
the carboxylic acid compound includes a tricarboxylic anhydride having an aromatic hydrocarbon group.

11. The polyamideimide according to claim 10, wherein the compound further includes a diamine having an aromatic hydrocarbon group.

12. The polyamideimide according to claim 1, wherein
the carboxylic acid compound includes a dicarboxylic acid having a linear saturated aliphatic hydrocarbon group where a number of carbon atoms is eight or more, and
the compound includes a diamine having an aromatic hydrocarbon group.

13. The polyamideimide according to claim 12, wherein the carboxylic acid compound further includes a tricarboxylic anhydride having an aromatic hydrocarbon group.

14. A polyamideimide containing liquid, comprising:
the polyamideimide according to claim 1, and a solvent.

15. A polyamideimide film, obtained by using the polyamideimide according to claim 1.

16. A printed board, obtained by using the polyamideimide according to claim 1.
